(19) United States
(12) Patent Application Publication
(10) Pub. No.: US 2011/0022907 A1
(43) Pub. Date: Jan. 27, 2011

(54) FPGA Test Configuration Minimization

(75) Inventors: Zhigang Jiang, Burlingame, CA (US); Shianling Wu, Princeton Junction, NJ (US); Samy Makar, Fremont, CA (US); Laung-Terng Wang, Sunnyvale, CA (US)

Correspondence Address: BACON & THOMAS, PLLC, 625 SLATERS LANE, FOURTH FLOOR, ALEXANDRIA, VA, 22314-1176, US

(73) Assignee: StarDFX Technologies, Inc., Sunnyvale, CA (US)

(21) Appl. No.: 12/689,791

(22) Filed: Jan. 19, 2010

Related U.S. Application Data
(60) Provisional application No. 61/219,570, filed on Jun. 23, 2009.

(51) Int. Cl. G01R 31/3177; G06F 11/25

(52) U.S. Cl. 714/725; 714/E11.155

(57) ABSTRACT

A method for automatically generating test patterns using a close-to-minimum number of configurations for a Field Programmable Gate Array (FPGA) to reduce test data volume and test application time. The FPGA can be a standalone programmable device or a circuit embedded in an Application Specific Integrated Circuit (ASIC).

### RELATED APPLICATION DATA

This application claims the benefits of U.S. Provisional Application No. 61/219,570 filed Jun. 23, 2009, which is hereby incorporated by reference.

### FIELD OF THE INVENTION

The present invention generally relates to the field of scan-based design and test using design-for-test (DFT) techniques. Specifically, the present invention relates to the field of testing of Field Programmable Gate Arrays (FPGAs).

### BACKGROUND

Design and manufacturing technology that started out as a small-scale Programmable Logic Array (PLA) has now advanced to very-large-scale Field Programmable Gate Arrays (FPGAs) and FPGA cores that are being embedded in System-on-Chip (SOC) applications. This has given users unprecedented power and flexibility in designing complex functions that are “programmable” in the field. As designers include more features into the structured arrays, methods and ways to fully test those programmable devices are often lagging. Unlike structural testing of its counterpart, Application Specific Integrated Circuits (ASICs), the main challenge in testing of programmable devices and programmable cores in SOCs has been the huge number of configurations that must be downloaded and tested to ensure end-product quality and/or in-system reliability.

Testing of programmable logic and routing resources is analogous to testing all possible functions (configurations) in anticipation for how the device will be configured by the end users in the field. Today, this testing is more art than science. There is no way humanly possible to tell if the test is complete or, more importantly, optimized. Furthermore, the download time to configure each programmable mode of operation is the dominant factor in test time and test cost during both manufacturing test and system-level test.

The first built-in self-test (BIST) method for FPGA was proposed by Stroud et al. (1996). This prior art approach exploits the re-programmability of FPGAs to create BIST circuitry in the FPGA during offline testing.

An FPGA test compression method is proposed by Tahoori et al. (2006). This prior art solution leverages the inherent regularity (array of identical blocks) of the FPGA in order to generate test configurations composed of identical Repeatable Test Modules (RTMs). With a slight enhancement to FGPA configuration loading facility, test configurations generated in this scheme can be loaded in parallel with a small amount of test data volume and test application time.

A new class of FPGAs with Special Function Blocks (SFBs) has recently emerged. These SFBs are essentially ASIC blocks embedded in an FPGA. In most cases, these SFBs perform different functions based on the configuration. Also, many of the inputs of these blocks come from programmable blocks of the FPGA. Therefore, previous techniques that target FPGA testing are not adequate for such blocks. Traditional Automatic Test Pattern Generation (ATPG) used for ASICs is insufficient because they require too many configurations to satisfy quality needs. Hence what is needed to test such blocks is an enhanced ATPG tool that is aware of configuration, and targets the minimization of configurations to achieve high quality test.

### SUMMARY OF THE INVENTION

The objective of the present invention is to expand on a proven technology, Automatic Test Pattern Generation (ATPG), used exclusively for developing manufacturing and system-level tests for ASICs, to perform effective configuration testing of the programmable devices as well as programmable logic and routing embedded in SOCs.

In light of the high cost associated with configuration download time of FPGA testing, the present invention first compiles an FPGA circuit and a given list of configuration bit names into a database, and then uses an ATPG that operates on the database to generate a plurality of test cubes specifically for configuration minimization. These test cubes are further merged in a post-process manner using a test cube merging method to generate FPGA test vectors that utilize a small number of configurations to reduce test time and hence test cost.

The test cube merging method may sort the test cubes in an increasing order with unspecified configuration bits into TC_A. Starting from the first test cube in TC_A, the method may merge all other test cubes in TC_A whose unspecified configuration bits are mergable with the first test cube to said first test cube, and then save the merged test cube to TC_B. The method may then delete the first test cube and all other test cubes in TC_A whose unspecified configuration bits are mergeable with the first test cube from TC_A, and repeat the process until TC_A is empty.

Furthermore, the test cube merging method may include a methodology to further reduce the number of test configurations if the number of test configurations produced from above resulted in a number of test configurations higher than expected. The methodology may rank the test configurations based on the number of test vectors generated. A configuration with more patterns is considered superior to one with fewer patterns. Then, the methodology may select top N configurations and constrain the ATPG tool to only use these configurations to generate new test vectors Tn. If the fault coverage of the generated Tn vectors is insufficient, then generate additional test vectors without placing any constraints on configuration bits. The methodology may then pick the top M configurations and constrain the ATPG tool to only use these M configurations to generate new test vectors Tm so that the final fault coverage of the FPGA circuit using the M+N test configurations is acceptable. There may be several iterations to result in the maximal use of M+N configurations.

The foregoing and additional objects, features and advantages of the invention will become more apparent from the following detailed description, which proceeds with reference to the following drawings.

### THE BRIEF DESCRIPTION OF DRAWINGS

FIG. 1 is a typical FPGA architecture;

FIG. 2 is a typical FPGA switch matrix structure;

FIG. 3 is a block diagram of the configuration minimization method in accordance with the present invention;

FIG. 4 illustrates how the test cube generated by ATPG is post-processed for configuration minimization purposes in accordance with the present invention;

FIG. 5 is an example illustrating the FPGA test cube merging method in accordance with the present invention; and

FIG. 6 is a block diagram of generating FPGA test cubes using ATPG in accordance with the present invention.

### DETAILED DESCRIPTION OF THE INVENTION

The following description is presently contemplated as the best mode of carrying out the present invention. This description is not to be taken in a limiting sense but is made merely for the purpose of describing the principles of the invention. The scope of the invention should be determined by referring to the appended claims.

The following discussion will be made clearer by a brief review of the relevant terminology as it is typically (but not exclusively) used. Accordingly, to assist readers in understanding the terminology used herein, the following definitions are provided.

“Configuration bits” are those FPGA SRAM cell bits used to configure the FPGA through switching on/off the connection of Programmable Interconnection Points (PIP), configuring I/O cells, etc.

A “Configuration” is a specific FPGA implementation when all configuration bits in the FPGA are specified.

A “test cube” is a string of bits including one or more unspecified bits (x's) in the configuration bits.

A “test vector” or a “test pattern” is a string of bits including only specified bits, such as 0's and 1's, in the configuration bits.

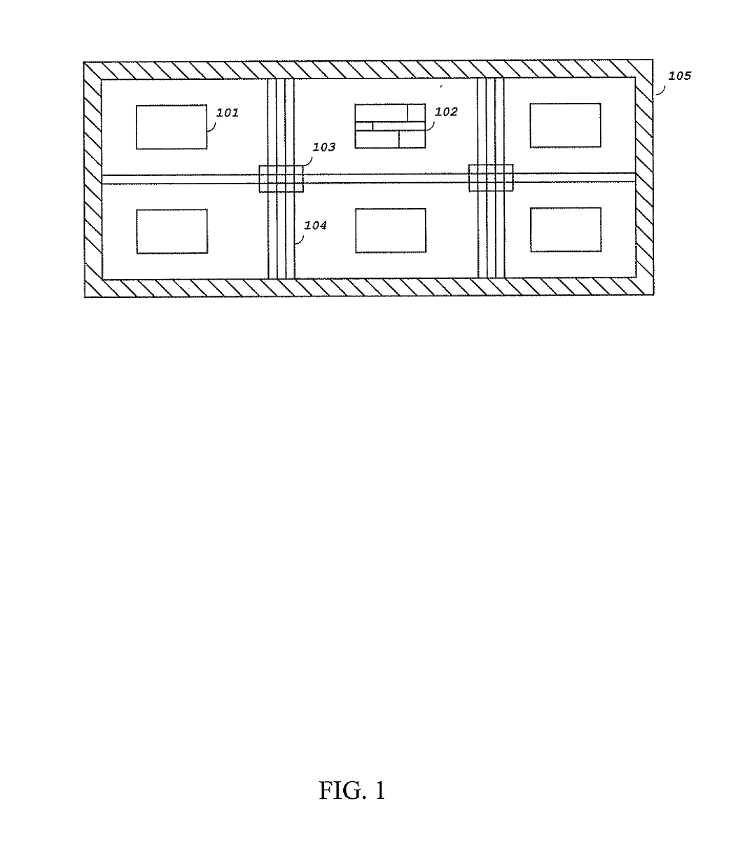

FIG. 1 shows a typical FPGA architecture. The FPGA architecture consists of a two-dimensional array of Programmable Logic Blocks (PLBs) 101 or specialized cores 102 interconnected by a programmable routing network 104 with programmable Input/Output (I/O) cells 105 at the periphery of the device. Interconnections among PLBs 101 or specialized cores 102 are programmed within switch matrices 103.

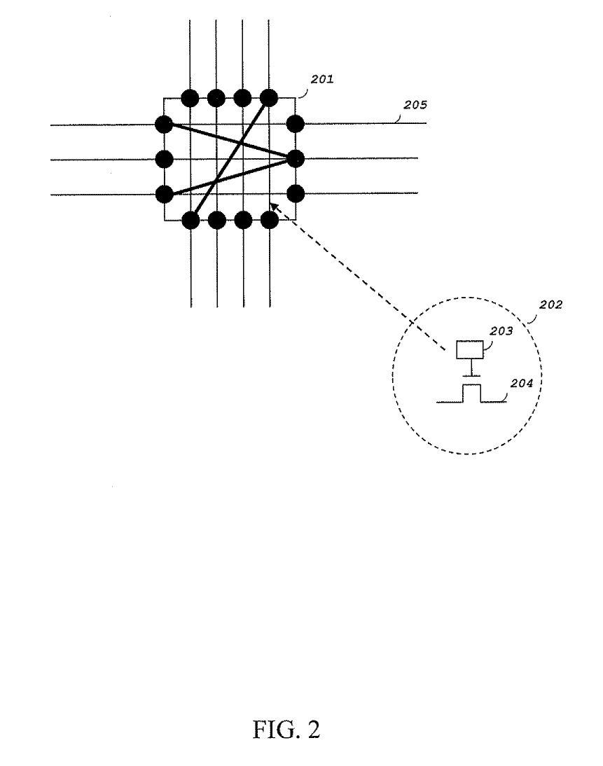

FIG. 2 shows a typical FPGA switch matrix structure. Within the switch matrix structure 201, programmable interconnections are made. Wire segments 205 are connected or disconnected by activating or deactivating Programmable Interconnection Points (PIPs) 202, respectively. Each PIP may comprise an SRAM cell 203 and a pass transistor 204. A logic value 1 in SRAM cell 203 enables the connection while a logical value 0 disables the connection. Typically, during a normal functional mode, each PIP is programmed by setting a proper logic value in its corresponding SRAM cell in the FPGA circuit first. The SRAM cell in the PIP used to store the logic value to configure the FPGA is referred to as a configuration bit. There may be two or more functional modes in a design. Therefore, during testing, an FPGA may have to be tested through many configurations. Overall test cost is dominated by the cost associated with the expensive downloading of all configurations required for thorough testing. Typically, a configuration is downloaded by serially shifting in all configuration bits through a very long chain of SRAM cells in the PIPs, which is very costly.

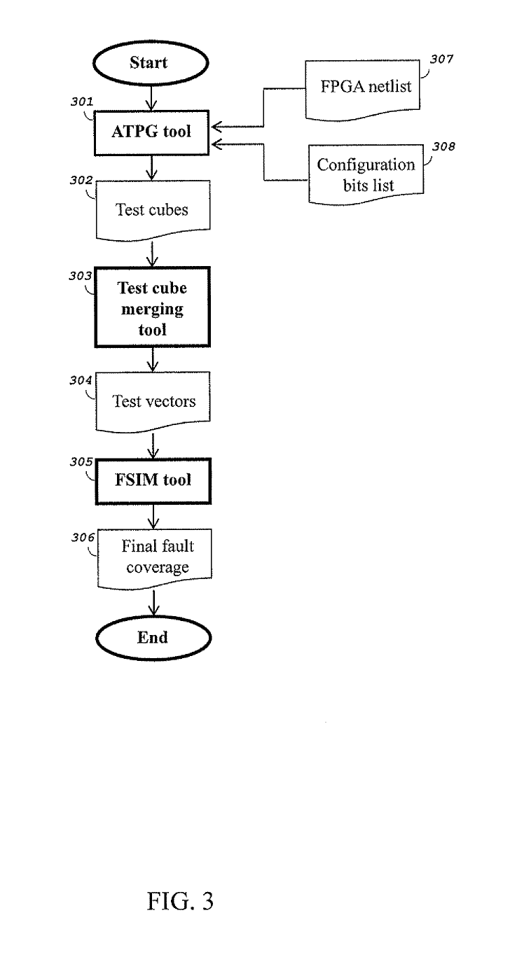

FIG. 3 shows an embodiment of a block diagram of an FPGA configuration minimization method according to the present invention. In this method, the FPGA's overall topology is represented in the form of a netlist that includes all configuration bits as primary inputs. This FPGA netlist 307 is readily readable by a conventional Automatic Test Pattern Generation (ATPG) tool 301. The ATPG tool 301 reads in both FPGA netlist 307 and the list of configuration bits 308 and generates test cubes 302 for given faults in the FPGA netlist 307. Test cubes 302 are generated in such a way that as many configuration bits in the configuration bits list 308 as possible are kept unspecified while the fault coverage of the ATPG generated vectors for the FPGA circuit is still sufficiently high.

Referring to FIG. 3, ATPG-generated test cubes 302 are further fed into a test cube merging tool 303. This test cube merging tool 303 merges test cubes 302 in such a way that the total number of configurations of generated test vectors 304 is minimized.

Referring to FIG. 3, the Fault Simulation (FSIM) tool 305 is further used to fault grade the generated test vectors 304 to obtain the final FPGA fault coverage 306.

It should be noted that the flow diagram may execute more than once each time to deal with a set of faults when the FPGA netlist is large. Each of the ATPG tool 301, test cube merging tool 303, and the FSIM tool 305, may be stand-alone or an embedded routine in a single executable program. A stand-alone executable program is commonly referred to as a tool.

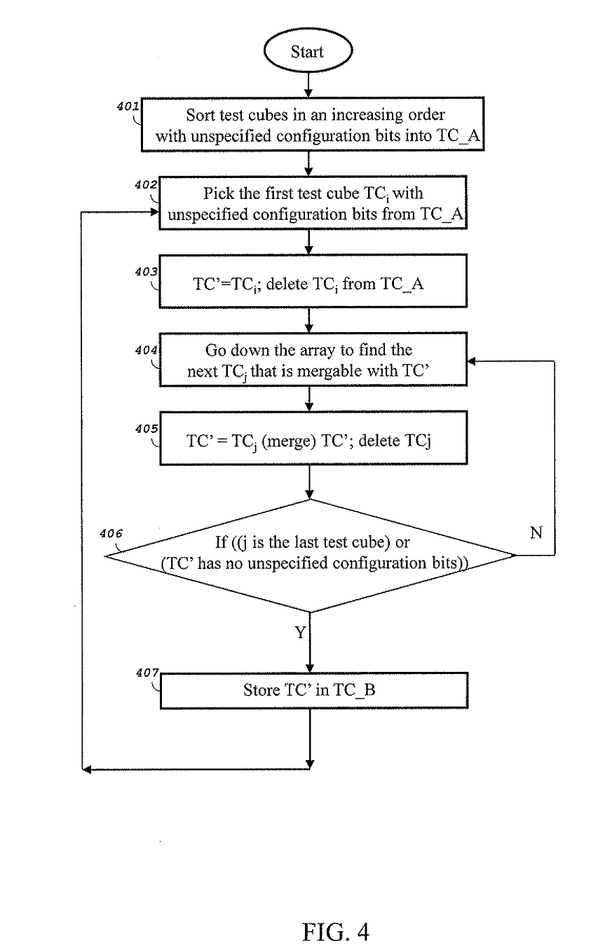

FIG. 4 shows an embodiment of a block diagram of a test cube merging method according to the present invention. The method starts with sorting ATPG-generated test cubes in an increasing order per the number of unspecified configuration bits 401 in each test cube. The sorted test cubes are stored in an array TC_A. TC_A is examined from the beginning to the end to find the first test cube TCᵢ that has at least one unspecified configuration bit 402. This TCᵢ is stored into TC′ and deleted from array TC_A 403. TC_A is further examined from TCᵢ downward to find the next TCⱼ that is mergeable with TC′. If one such TCⱼ is found, TC′ is merged with TCⱼ to form a new TC′ and TCⱼ is deleted from TC_A 405. Once the end of TC_A is reached or all configuration bits in TC′ are specified, the final TC′ is stored in another test vector set TC_B 407. The rest of the test cubes in TC_A are processed in a similar fashion to keep generating TC′ to be stored in TC_B until the set TC_A is empty. TC_B is then a low-cost FPGA test set so obtained that uses a minimum or close-to-minimum number of configurations for testing the FPGA netlist.

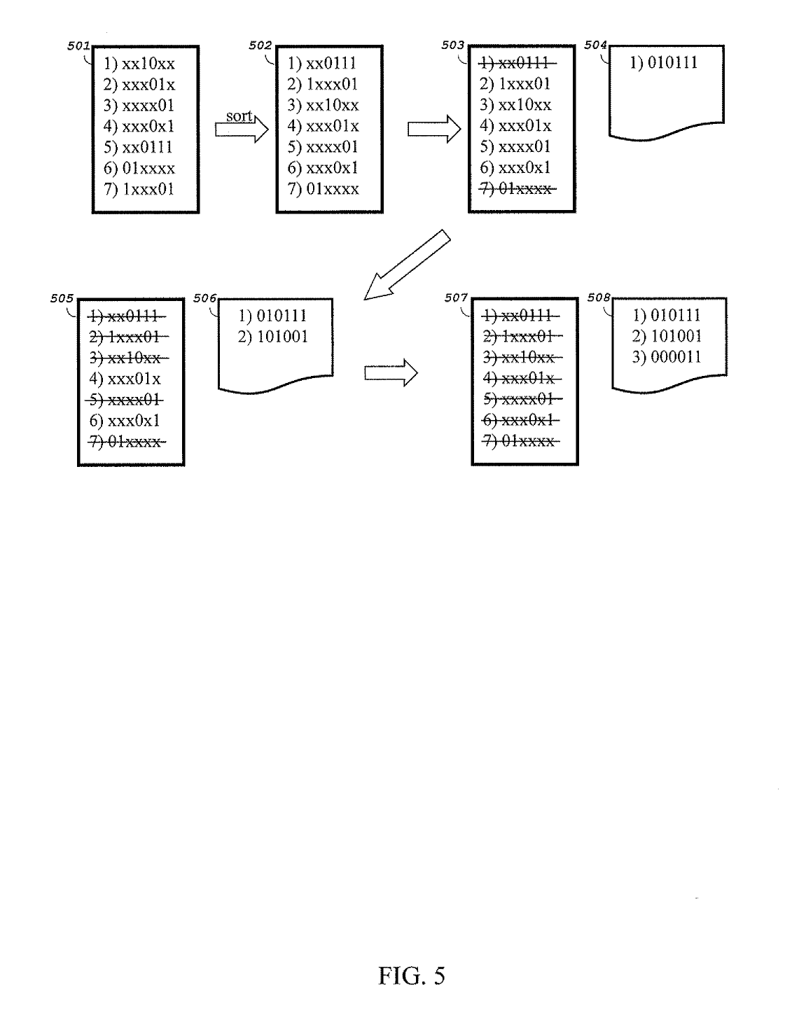

FIG. 5 shows an example of a test cube merging method according to the present invention. Test cube list 501 is a set of test cubes generated by ATPG for configuration minimization purpose. Without loss of generality, only configuration bits of each test cube are shown in this example. This ATPG-generated test cube set is first sorted in an increasing order per the number of unspecified configuration bits. The sorted test cubes 502 are processed to generate test vectors with minimized configurations. For example, test cube xx0111 has only two unspecified configuration bits; the other test cubes have 3 or 4 unspecified bits. Thus, the test cube xx0111 is placed on top of the test cube list first.

Referring to FIG. 5, the first test cube xx0111 in the list 502 is picked and deleted from the list. The rest of the test cubes in the list 502 are checked to identify one that is mergeable with xx0111. The last test cube 01xxxx in the list 502 is found to be mergeable with xx0111. So the test cube 01xxxx is also deleted from the list 502. A test vector 010111 obtained by merging xx0111 and 01xxxx is stored in the vector list 504, because there are no unspecified configuration bits in the merged test vector 010111. With two test cubes deleted, the test cube list 503 only has five test vectors left to process now.

Referring to FIG. 5, the first test cube 1xxx01 remaining in the list 503 is picked and the rest of the test cubes in the list 503 are checked for merging candidates. The second test cube xx10xx is found to be mergeable with 1xxx01 and the resulting vector from merging is 1x1001. The merging result 1x1001 is further checked with other remaining test cubes. The fifth test cube xxxx01 is found to be mergeable with 1x1001. Their merged result is still 1x1001. After further randomly filling the only “x” in 1x1001, a second test vector 101001 is obtained and is added into the test vector list 506. The three test cubes participating in the merging are further deleted to form a test cube array 505.

Referring to FIG. 5, the first remaining test cube xxx01x is picked and the only other remaining cube xxx0x1 is found to be mergeable. The resulting test vector 000011 is added into the test vector list 508. Since the test cube list 507 is empty after this step, the test vector list 508 is the final test vector set.

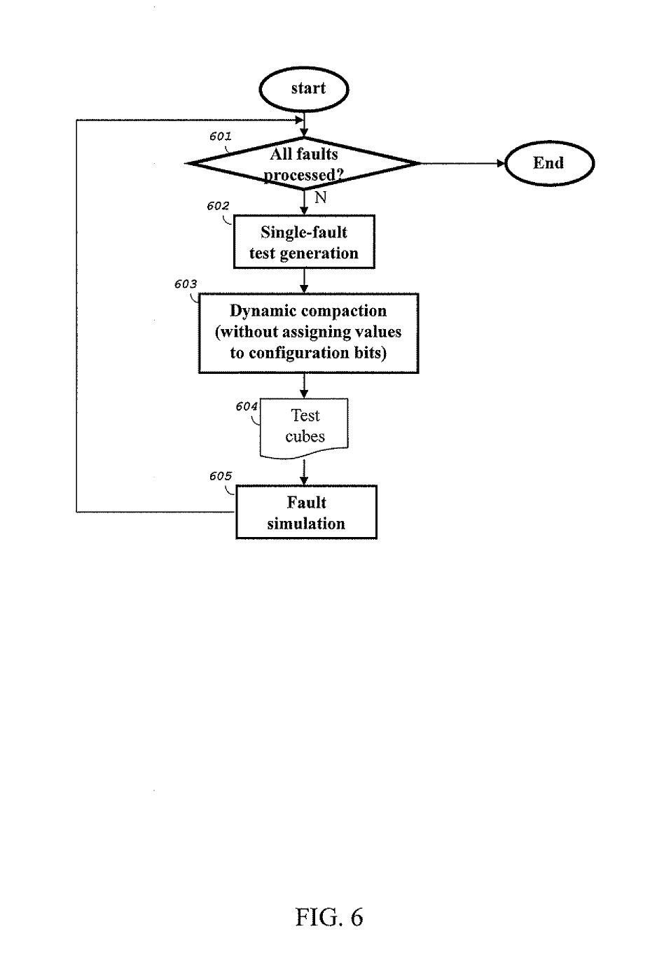

FIG. 6 shows an embodiment of a flow diagram of an FPGA test cube generation method using ATPG according to the present invention. As long as there is one fault f remained unprocessed, the ATPG tool will perform single-fault test generation for this fault f 602. During single-fault test generation 602, all configuration bits are treated equally as normal primary inputs and are assigned logic values as needed.

Referring to FIG. 6, upon the successful completion of single-fault test generation 602, an optional dynamic compaction step 603 may be further performed attempting to detect more faults by further specifying logic values at primary inputs. Dynamic compaction 603 is different from conventional ATPG in that no logic value assignment is allowed at any configuration bit.

Referring to FIG. 6, the test cube 604 generated may be fault-simulated 605 to identify other faults that can also be detected. The test cube 604 is saved and the iterative loops of single-fault test generation 602, optional dynamic compaction 603, and fault simulation 605 are being performed until a complete given list of faults in the FPGA under test is being processed.

A methodology for using this ATPG algorithm to further minimize the number of configurations is described here. After generating patterns with the above described algorithm, a large number of configurations may be observed. First, the configurations are ranked based on the number of ATPG generated vectors. A configuration with more patterns is considered superior to one with fewer patterns.

Now, select the top N configurations. Constrain the ATPG tool to only use these configurations. Create new patterns (Tn). This approach maximizes the use of these N configurations. The value of N depends on tester capacity for loading configurations, and can be easily decided upfront. In most cases, with N=15, such a run provides coverage very close (within 1%) to the unconstrained coverage.

In cases where coverage of Tn patterns is insufficient, more work would be needed. Use the undetected fault list from Tn to create a new set of patterns. These patterns would not contain any restrictions. This time, pick the top M configurations and create patterns with the restricted fault list. Repeat the experiment with different combinations of N and M, such that the resulting sum of N and M, N+M, satisfies the tester budget. Select the best combination that gives the highest fault coverage. Create a complete test set that constrains the ATPG tool to those configurations. This approach, although more complex than the previous one, was able to handle all cases for M+N=15, and provide coverage within 1% of the original coverage.

Having thus described presently preferred embodiments of the present invention, it can now be appreciated that the objectives of the invention have been fully achieved. And it will be understood by those skilled in the art that many changes in construction & circuitry, and widely differing embodiments and applications of the invention will suggest themselves without departing from the spirit and scope of the present invention. The disclosures and the description herein are intended to be illustrative and are not in any sense limitation of the invention, more preferably defined in the scope of the invention by the Claims appended hereto and their equivalents.

What is claimed is:

1. A method for reducing the number of test configurations for testing a Field Programmable Gate Array (FPGA) circuit, the FPGA circuit comprising a plurality of configuration bits that are programmable to switch on/off the connections, a test configuration being an FGPA circuit with each configuration bit programmed to a specified logic value (0 or 1), the method comprises:
a) Compiling the FPGA circuit that includes a list of FPGA configuration bit names into a database;
b) Using an Automatic Test Pattern Generation (ATPG) tool that operates on the database to generate a plurality of test cubes, wherein one or more test cubes may include one or more unspecified bits (X's) in the configuration bits; and
c) Using a test cube merging tool that operates on the set of test cubes to merge the configuration bits in the test cubes into a plurality of test vectors that result in a smaller number of test configurations.

2. The method of said claim 1, wherein said configuration bit in said FPGA circuit includes an SRAM cell and a pass transistor.

3. The method of said claim 1, where in said test cube merging tool further comprises fault-grading the plurality of test vectors using a fault simulation (FSIM) tool to obtain a final fault coverage for a select set of faults.

4. The method of said claim 1, wherein said ATPG tool further comprises the following steps to generate a set of test cubes for a given list of faults:
a) Generate a test cube for a select fault in said given list of faults;
b) Perform a dynamic compaction without assigning values to configuration bits;
c) Perform a fault simulation to detect additional faults in said given list of faults.

5. The method of said claim 1, wherein said ATPG tool further comprises the following steps to generate a set of test cubes for a given list of faults:
a) Generate a test cube for a select set of faults in said given list of faults;
b) Perform a fault simulation to detect additional faults in said given list of faults.

6. The method of said claim 1, wherein said test cube merging tool further comprises the following steps to reduce the number of test configurations and produce a smaller set of test vectors TC_B:
a) Sort the test cubes in an increasing order with unspecified configuration bits into TC_A;
b) Starting from the first test cube in TC_A, merge all other test cubes in TC_A whose unspecified configuration bits are mergable with said first test cube to said first test cube, and then save the merged test cube to TC_B;
c) Delete said first test cube and said all other test cubes in TC_A whose unspecified configuration bits are mergable with said first test cube from TC_A; and
d) Repeat steps b and c, until TC_A is empty.

7. The method of claim 1 further comprising the following steps to further reduce the number of test configurations after test cube merging:
a) Rank the test configurations based on the number of test vectors generated;
b) Select the top N configurations; Constrain the ATPG tool to only use these configurations to generate new test vectors Tn;
c) If the fault coverage of the generated Tn patterns is insufficient, generate additional test vectors without placing any constraints on configuration bits; and pick the top M configurations and constrain the ATPG tool to only use these M configurations to generate new test vectors Tm so that the final fault coverage using the M+N test configurations is acceptable.
